(19) United States
(12) Patent Application Publication
(10) Pub. No.: US 2024/0333231 A1
(43) Pub. Date: Oct. 3, 2024

(54) POWER AMPLIFIER CIRCUIT

(71) Applicant: Murata Manufacturing Co., Ltd., Kyoto (JP)

(72) Inventors: Masatoshi HASE, Kyoto (JP); Seiko NETSU, Kyoto (JP); Shingo YANAGIHARA, Kyoto (JP)

(21) Appl. No.: 18/619,743

(22) Filed: Mar. 28, 2024

(30) Foreign Application Priority Data
Mar. 31, 2023 (JP) 2023-057063

(51) Int. Cl. H03F 1/32; H03F 1/02; H03F 3/24; H03F 3/60

(52) U.S. Cl. CPC H03F 1/3211; H03F 1/0288; H03F 3/245; H03F 3/602; H03F 2200/451

(57) ABSTRACT

A power amplifier circuit includes a distortion compensation amplifier circuit that includes a first amplifier that amplifies a first signal distributed from an input signal, and a second amplifier connected in parallel to the first amplifier, that amplifies a second signal distributed from the input signal and having a different phase from the first signal, and outputs an amplified signal obtained by combining a signal output from the first amplifier and the second amplifier, and an output amplifier circuit that outputs an output signal obtained by amplifying the amplified signal. The distortion compensation amplifier circuit further includes a control circuit that controls, based on power of the input signal, the first gain and the second gain to compensate for a change in a phase of the output amplifier circuit with respect to a change in the power of the signal input to the output amplifier circuit.

### CROSS REFERENCE TO RELATED APPLICATION

This application claims priority from Japanese Patent Application No. 2023-057063 filed on Mar. 31, 2023. The content of this application is incorporated herein by reference in its entirety.

### BACKGROUND ART

The present disclosure relates to a power amplifier circuit.

In various multi-carrier communication systems such as wireless and satellite communication, a digital modulation method is widely used for improvement of communication capacity and high data communication speed. Information transmitted in the digital modulation method is subjected to modulation and then transmitted as included in both an amplitude of a signal and a phase thereof. Japanese Unexamined Patent Application Publication No. 2001-223539 discloses a linear amplifier that improves, when such a signal is amplified and transmitted, distortion of an amplitude characteristic and a phase characteristic, which may deteriorate quality of the signal.

### BRIEF SUMMARY

In the linear amplifier described in Japanese Unexamined Patent Application Publication No. 2001-223539, an active feedforward predistorter is connected in parallel to a driver-stage amplifier. The active feedforward predistorter is designed to have a gain and a phase response opposite to a gain and a phase response of a final-stage power amplifier as an input power level changes. That is, the active feedforward predistorter distorts an input signal in advance in a driver-stage power amplifier to compensate for nonlinearity of the final-stage power amplifier. Accordingly, output linearity of the linear amplifier as a whole can be improved.

However, the active feedforward predistorter is configured to compensate for the nonlinearity of the final-stage amplifier with a diode (bipolar transistor whose collector is grounded through a capacitor) having characteristics different from those of the final-stage power amplifier configured with transistors. Therefore, in the linear amplifier, there is a problem that operating conditions (for example, frequency, temperature, output region, and the like) under which a compensation effect is obtained are limited.

The present disclosure provides a power amplifier circuit that can improve signal quality under a wider operating condition.

A power amplifier circuit according to one aspect of the present disclosure includes a distortion compensation amplifier circuit that includes a first amplifier that amplifies a first signal distributed from an input signal with a first gain, and a second amplifier, which is connected in parallel to the first amplifier, that amplifies a second signal distributed from the input signal and having a different phase from the first signal with a second gain, and outputs an amplified signal obtained by combining a signal output from the first amplifier and a signal output from the second amplifier, and an output amplifier circuit that outputs an output signal obtained by amplifying the amplified signal. The distortion compensation amplifier circuit further includes a control circuit that controls, based on power of the input signal, the first gain and the second gain to compensate for a change in a phase of the output amplifier circuit with respect to a change in the power of the signal input to the output amplifier circuit.

According to the present disclosure, it is possible to provide the power amplifier circuit that can improve the signal quality under a wider operating condition.

### BRIEF DESCRIPTION OF THE DRAWINGS

FIG. 1 is a diagram showing a configuration example of a power amplifier circuit according to a first embodiment;

FIGS. 2A and 2B are diagrams showing a configuration example of a distortion compensation amplifier circuit;

FIG. 3 is a diagram showing a detailed configuration example of the distortion compensation amplifier circuit;

FIG. 4 is a graph showing a relationship between collector currents of a transistor Tr3 and a transistor Tr4 and an input signal RFin;

FIG. 5 is a graph showing a relationship between collector voltages of the transistor Tr3 and the transistor Tr4 and the input signal RFin;

FIG. 6 is a diagram showing a configuration example of a distortion compensation amplifier circuit according to a first modification example;

FIG. 7 is a diagram showing a configuration example of a distortion compensation amplifier circuit according to a second modification example;

FIG. 8 is a diagram showing a configuration example of a distortion compensation amplifier circuit according to a third modification example;

FIG. 9 is a diagram showing a configuration example of a power amplifier circuit according to a second embodiment;

FIG. 10 is a diagram showing a configuration example of a power amplifier circuit according to a third embodiment;

FIG. 11 is a diagram showing a modification example of the power amplifier circuit according to the third embodiment;

FIG. 12 is a diagram showing a modification example of the power amplifier circuit according to the third embodiment; and

FIG. 13 is a diagram showing a disposition example of each component of the power amplifier circuit.

### DETAILED DESCRIPTION

Hereinafter, embodiments of the present disclosure will be described in detail with reference to accompanying drawings. The same reference numerals are assigned to the same elements, and redundant descriptions are omitted.

### Power Amplifier Circuit 100a According to First Embodiment

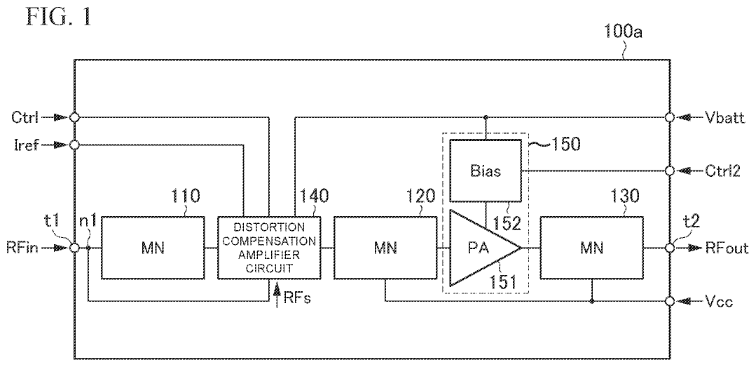

A power amplifier circuit 100a according to a first embodiment will be described with reference to FIG. 1. FIG. 1 is a diagram showing a configuration example of the power amplifier circuit 100a according to the first embodiment. A power amplifier circuit 100a shown in FIG. 1 is mounted on, for example, a mobile communication device such as a cellular phone, and is used to amplify power of a radio-frequency (RF) signal to be transmitted to a base station.

The power amplifier circuit 100a amplifies power of a signal of a communication standard, for example, a second generation mobile communication system (2G), a third generation mobile communication system (3G), a fourth generation mobile communication system (4G), a fifth generation mobile communication system (5G), long term evolution (LTE)-frequency division duplex (FDD), LTE-time division duplex (TDD), LTE-Advanced, or LTE-Advanced Pro. Further, a frequency of the RF signal is, for example, approximately several hundreds of MHz to several tens of GHz. The communication standard of the signal amplified by the power amplifier circuit 100a and the frequency thereof are not limited thereto.

The power amplifier circuit 100a compensates for nonlinearity of an amplitude and a phase with respect to fluctuations of the input signal RFin. The power amplifier circuit 100a includes, for example, an input matching circuit 110, an inter-stage matching circuit 120, an output matching circuit 130, a distortion compensation amplifier circuit 140, and an output amplifier circuit 150.

The input matching circuit 110 is provided at a previous stage of the distortion compensation amplifier circuit 140, and causes impedance of an input terminal t1 and the distortion compensation amplifier circuit 140 to match.

The inter-stage matching circuit 120 is provided at a subsequent stage of the distortion compensation amplifier circuit 140, and causes impedance of the distortion compensation amplifier circuit 140 and the output amplifier circuit 150 to match.

The output matching circuit 130 is provided at a subsequent stage of the output amplifier circuit 150, and causes impedance of the output amplifier circuit 150 and a circuit (not illustrated) at a subsequent stage of an output terminal t2 to match.

The distortion compensation amplifier circuit 140 amplifies the input signal RFin input from the input terminal t1 through the input matching circuit 110, and outputs an amplified signal RFap to the output amplifier circuit 150 through the inter-stage matching circuit 120. The distortion compensation amplifier circuit 140 adjusts, based on a signal (hereinafter referred to as “input control signal RFs”) branched from the input signal RFin, the phase to compensate for a change in the phase of the output amplifier circuit 150 (such that the phase changes in a direction opposite to the change in the phase of the output amplifier circuit 150), and outputs the amplified signal RFap. The change in the phase of the output amplifier circuit 150 indicates, for example, the change in the phase of the signal output from the output amplifier circuit 150, and the same applies when the same expression is used in the following.

The output amplifier circuit 150 outputs, to an output terminal out through the output matching circuit 130, an output signal RFout obtained by amplifying the amplified signal RFap output from the distortion compensation amplifier circuit 140. The output amplifier circuit 150 includes an output amplifier 151 and an output bias circuit 152. The output amplifier 151 is configured to include, for example, a transistor, and amplifies the amplified signal RFap and outputs the output signal RFout. The output bias circuit 152 supplies a bias for adjusting a gain to the output amplifier 151 (for example, a base of the transistor).

The distortion compensation amplifier circuit 140 and the output amplifier circuit 150 are configured to include, for example, a bipolar transistor such as a heterojunction bipolar transistor (HBT). The distortion compensation amplifier circuit 140 and the output amplifier circuit 150 may be configured to include a metal-oxide-semiconductor field-effect transistor (MOSFET) instead of the HBT. In the present embodiment, description will be performed on the assumption that the distortion compensation amplifier circuit 140 and the output amplifier circuit 150 are configured of the bipolar transistor.

As described above, in the power amplifier circuit 100a, the distortion compensation amplifier circuit 140 and the output amplifier circuit 150 have the same linearity, and thus the change in the phase of the output amplifier circuit 150 can be compensated under wide operating conditions (for example, frequency, temperature, output region, and the like).

In the present embodiment, as an example, description will be performed on the assumption that the power amplifier circuit 100a is configured to amplify the power in two stages, but the present disclosure is not limited thereto. For example, the power amplifier circuit 100a may be configured to amplify the power in three or more stages.

### Configuration of Distortion Compensation Amplifier Circuit 140

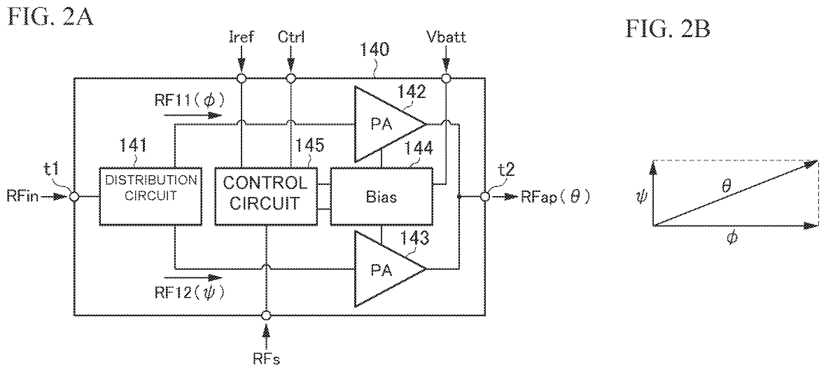

An example of the configuration of the distortion compensation amplifier circuit 140 will be described with reference to FIGS. 2A and 2B. FIGS. 2A and 2B are diagrams showing a configuration example of the distortion compensation amplifier circuit 140.

As shown in FIG. 2A, the amplifier circuit 140 includes, for example, a distribution circuit 141, an amplifier 142, an amplifier 143, a bias circuit 144, and a control circuit 145.

The distribution circuit 141 distributes the input signal RFin into a signal RF11 (first signal) and a signal RF12 (second signal) having a different phase from the signal RF11. In the power amplifier circuit 100a, as an example, description will be performed on the assumption that the distribution is performed into the signal RF11 and the signal RF12 having a different phase from the signal RF11 by 90 degrees in the distribution circuit 141. The 90 degrees includes a case of being approximately 90 degrees, and includes, for example, a range of 45 degrees to 125 degrees. The distribution circuit 141 may be configured to include, for example, a distributed constant circuit such as a balun or a coupling line 3 dB coupler, a Wilkinson distributor, or a web distributor. Further, the distribution circuit 141 may include, for example, a fixed phase shift circuit including one or more inductors and one or more capacitors. In FIGS. 2A and 2B, the phase of the signal RF11 is indicated by φ, and the phase of the signal RF12 is indicated by ψ.

The amplifier 142 amplifies the signal RF11. The amplifier 143 amplifies the signal RF12. The bias is supplied to each of the amplifier 142 and the amplifier 143 from the bias circuit 144 controlled by the control circuit 145 which will be described below.

The bias circuit 144 supplies the bias to the amplifier 142 and the amplifier 143. The bias supplied from the bias circuit 144 is controlled by the control circuit 145 which will be described below. Hereinafter, description will be performed on the assumption that the bias supplied to the amplifier 142 from the bias circuit 144 is referred to as “first bias”, and the bias supplied to the amplifier 143 from the bias circuit 144 is referred to as “second bias”.

The control circuit 145 controls the magnitude of each of the first bias and the second bias, which are supplied from the bias circuit 144. The input control signal RFs is input to the control circuit 145. The input control signal RFs is, for example, a signal branched from the input signal RFin at a node n1 (refer to FIG. 1) between an input terminal in and the input matching circuit 110. Further, a reference current Iref and a control signal ctrl are input to the control circuit 145.

As described above, in the distortion compensation amplifier circuit 140, the distribution circuit 141 distributes the input signal RFin into the signal RF11 and the signal RF12 having different phases by approximately 90 degrees, the amplifier 142 to which the first bias is supplied amplifies the signal RF11, and the amplifier 143 to which the second bias is supplied amplifies the signal RF12.

Accordingly, as shown in FIG. 2B, the distortion compensation amplifier circuit 140 outputs the amplified signal RFap indicating the gain and the phase as indicated by a vector θ. The vector φ indicates a signal output from the amplifier 142, indicates the magnitude of the signal by a vector length, and indicates the phase of the signal by a vector direction. Similarly, the vector ψ indicates a signal output from the amplifier 143.

That is, the distortion compensation amplifier circuit 140 controls, based on the power of the input signal RFin, the gain of the amplifier 142 (first gain) and the gain of the amplifier 143 (second gain) to compensate for the change in the phase of the output amplifier circuit 150 with respect to a change in power of the signal input to the output amplifier circuit 150. As described above, with the control of the gain of the amplifier 142 and the gain of the amplifier 143, the distortion compensation amplifier circuit 140 can output the amplified signal RFap whose phase is adjusted, which can compensate for the change in the phase of the output amplifier circuit 150.

### Detailed Configuration of Distortion Compensation Amplifier Circuit 140

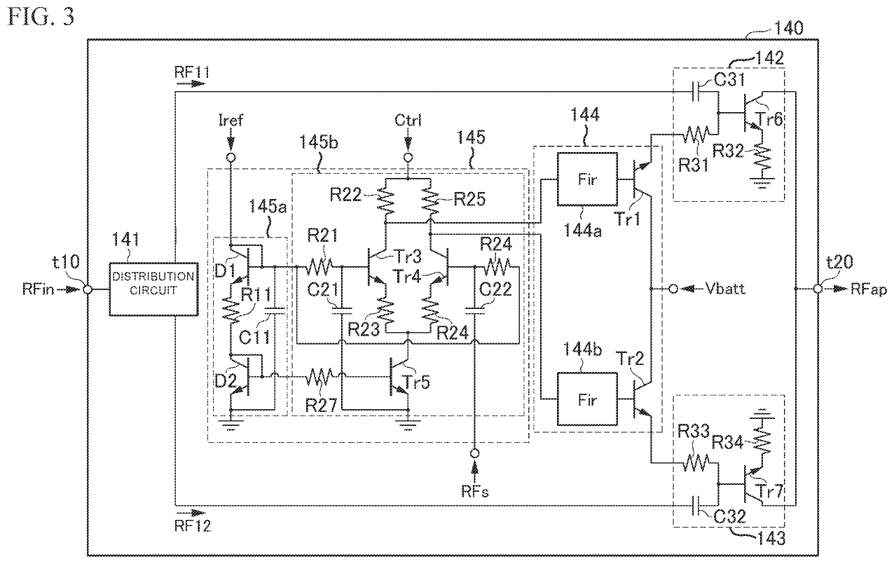

A detailed configuration of the distortion compensation amplifier circuit 140 will be described with reference to FIG. 3. FIG. 3 is a diagram showing a detailed configuration example of the distortion compensation amplifier circuit 140. Hereinafter, for convenience, the control circuit 145, the bias circuit 144, and the amplifiers 142 and 143 will be described in order.

The control circuit 145 includes a reference circuit 145a and a bias control circuit 145b.

The reference circuit 145a is a circuit that supplies the reference current Iref to the bias control circuit 145b. In the reference circuit 145a, a diode-connected transistor D1 and a diode-connected transistor D2 are connected in series through a resistor R11. The reference current Iref is supplied to a collector (anode) of the transistor D1. A base of the transistor D1 is electrically coupled to a reference potential through a capacitor C11 for attenuating a high frequency component. An emitter (cathode) of the transistor D2 is electrically coupled to the reference potential.

The bias control circuit 145b controls the magnitude of each of the first bias and the second bias, which are supplied from the bias circuit 144, based on the power of the input control signal RFs (input signal RFin). The bias control circuit 145b includes a transistor Tr3, a transistor Tr4, and a transistor Tr5. The transistor Tr3 and the transistor Tr4 form a differential pair.

The transistor Tr3 has a base that is electrically connected to the base of the transistor D1 through a resistor R21, a collector that receives the control signal ctrl through a resistor R22, and an emitter that is electrically connected to a collector of the transistor Tr5 through a resistor R23. The base of the transistor Tr3 is electrically coupled to the reference potential through a capacitor C21 for attenuating the high frequency component. The collector of the transistor Tr3 is electrically connected to a base of a transistor Tr1 of the bias circuit 144.

The transistor Tr4 has a base that is electrically connected to the base of the transistor D1 through a resistor R24, a collector that receives the control signal ctrl through a resistor R25, and an emitter that is electrically connected to the collector of the transistor Tr5 through a resistor R26. The input control signal RFs is input to the base of the transistor Tr4 through a capacitor C22. The collector of the transistor Tr4 is electrically coupled to a base of a transistor Tr2 of the bias circuit 144.

The transistor Tr5 has a base that is electrically connected to a base of the transistor D2 through a resistor R27, and an emitter that is electrically coupled to the reference potential.

The bias circuit 144 includes the transistor Tr1, the transistor Tr2, a filter circuit 144a, and a filter circuit 144b.

The transistor Tr1 has the base that is electrically connected to the collector of the transistor Tr3 through the filter circuit 144a, a collector that is supplied with a constant voltage Vbatt, and an emitter that is electrically connected to a base of a transistor Tr6 of the amplifier 142 which will be described below.

The transistor Tr2 has the base that is electrically connected to the collector of the transistor Tr4 through the filter circuit 144b, a collector that is supplied with the constant voltage Vbatt, and an emitter that is electrically connected to a base of a transistor Tr7 of the amplifier 143 which will be described below.

The filter circuit 144a and the filter circuit 144b cause the high frequency component to attenuate.

The amplifier 142 is a circuit that amplifies the signal RF11 distributed by the distribution circuit 141. The amplifier 142 includes the transistor Tr6, a resistor R31, a capacitor C31, and a resistor R32. The transistor Tr6 has the base that receives the signal RF11 through the capacitor C31, a collector that is electrically connected to an output terminal t20, and an emitter that is electrically coupled to the reference potential through the resistor R32. The base of the transistor Tr6 is electrically connected to the emitter of the transistor Tr1 of the bias circuit 144 through the resistor R31, and is supplied with the bias.

The amplifier 143 is a circuit that amplifies the signal RF12 having a different phase from the signal RF11, which is distributed by the distribution circuit 141. The amplifier 143 includes the transistor Tr7, a resistor R33, a capacitor C32, and a resistor R34. The transistor Tr7 has the base that receives the signal RF12 through the capacitor C32, a collector that is electrically connected to the output terminal t20, and an emitter that is electrically coupled to the reference potential through the resistor R34. The base of the transistor Tr7 is electrically connected to the emitter of the transistor Tr2 of the bias circuit 144 through the resistor R33, and is supplied with the bias.

### Operation of Distortion Compensation Amplifier Circuit 140

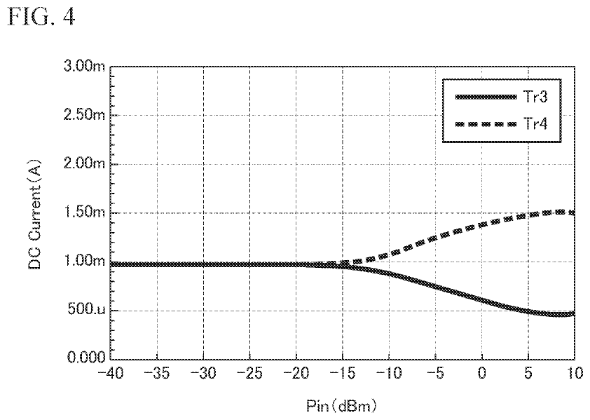

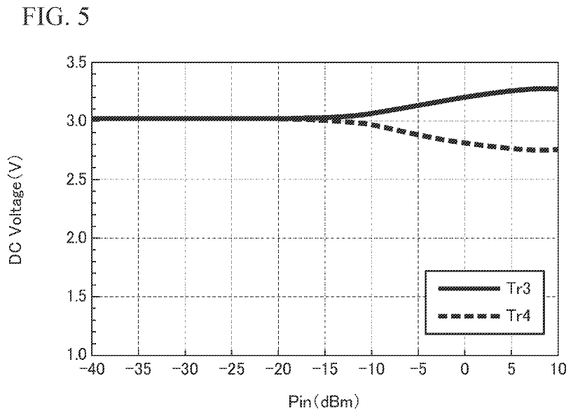

Next, an operation of the distortion compensation amplifier circuit 140 will be described with reference to FIGS. 3, 4, and 5. FIG. 4 is a graph showing a relationship between collector currents of the transistor Tr3 and the transistor Tr4 and the input signal RFin. In FIG. 4, the vertical axis indicates the magnitude of the collector current (A), and the horizontal axis indicates the magnitude (dBm) of the input signal RFin. FIG. 5 is a graph showing a relationship between collector voltages of the transistor Tr3 and the transistor Tr4 and the input signal RFin. In FIG. 5, the vertical axis indicates the collector voltage (V), and the horizontal axis indicates the power (dBm) of the input signal RFin.

In the control circuit 145, the control signal ctrl having a constant voltage is supplied to the collectors of the transistor Tr3 and the transistor Tr4 of the differential pair. Further, a constant bias is supplied from the reference circuit 145a to the bases of the transistor Tr3, the transistor Tr4, and the transistor Tr5. That is, in the control circuit 145, a constant current is extracted by the transistor Tr5 from the emitters of the transistor Tr3 and the transistor Tr4 of the differential pair. The input control signal RFs is input to the base of the transistor Tr4.

When the power of the input control signal RFs increases (when the power of the input signal RFin increases), a current obtained by combining an emitter current of the transistor Tr3 and an emitter current of the transistor Tr4 is constant, while the emitter current of the transistor Tr4 increases. Thus, the emitter current of the transistor Tr3 decreases. Similarly, when the power of the input control signal RFs decreases, the emitter current of the transistor Tr4 decreases.

As described above, the control circuit 145 operates, based on the power of the input signal RFin, such that when the emitter current of any one of the transistor Tr3 or the transistor Tr4 increases, the emitter current of the other transistor decreases. That is, the control circuit 145 operates such that the emitter currents of the transistor Tr3 and the transistor Tr4 are further not balanced as the power of the input signal RFin increases.

In the bias circuit 144, a current corresponding to the collector currents of the transistor Tr3 and the transistor Tr4 is supplied to the base of the transistor Tr1 and the base of the transistor Tr2.

As shown in FIG. 4, in the bias circuit 144, the collector current (broken line) of the transistor Tr4 increases as the power of the input control signal RFs (input signal RFin on the horizontal axis) increases, as described above. That is, since the base current of the transistor Tr2 increases, the emitter current increases. Accordingly, in the amplifier 143, since a voltage drop at the resistor 33 increases, the collector current of the amplifier 143 decreases.

On the other hand, as shown in FIG. 4, in the bias circuit 144, the collector current (solid line) of the transistor Tr3 decreases as the power of the input control signal RFs (input signal RFin on the horizontal axis) increases. That is, since the base current of the transistor Tr1 decreases, the emitter current decreases. Accordingly, in the amplifier 142, since the voltage drop at the resistor 31 decreases, the collector current of the amplifier 142 increases. Here, as shown in FIG. 5, the collector voltage of the transistor Tr4 indicates characteristics opposite to those of the collector current.

As described above, in the distortion compensation amplifier circuit 140, the outputs of the amplifier 142 and the amplifier 143 are not balanced as the power of the input signal RFin increases. A degree of imbalance can be set by, for example, adjusting the reference current Iref and the control signal ctrl. A change direction of a phase characteristic can be adjusted by switching the transistor to which the input control signal RFs is input (here, switched to the transistor Tr3).

That is, in the distortion compensation amplifier circuit 140, a length of the vector φ indicating the magnitude of the output of the amplifier 142 and a length of the vector ψ indicating the magnitude of the output of the amplifier 143, in the vector diagram of FIG. 2B, are adjusted to adjust the phase of the output. Further, the distribution circuit 141 of the distortion compensation amplifier circuit 140 can adjust a phase difference between the vector φ and the vector ψ. As described above, with the adjustment of the phase difference between the amplifier 142 and the amplifier 143 in the distribution circuit 141 based on the power of the input signal RFin and the further adjustment of the bias (gain) between the amplifier 142 and the amplifier 143, the distortion compensation amplifier circuit 140 can output the amplified signal RFap whose phase changes in the direction opposite to the phase change of the output amplifier circuit 150.

From the above, with the specification of the phase characteristic of the output amplifier circuit 150 in advance and the provision of the distortion compensation amplifier circuit 140 having the phase characteristic that changes in the direction opposite to the phase characteristic, the linearity of the gain of the power amplifier circuit 100a can be improved.

### First Modification Example

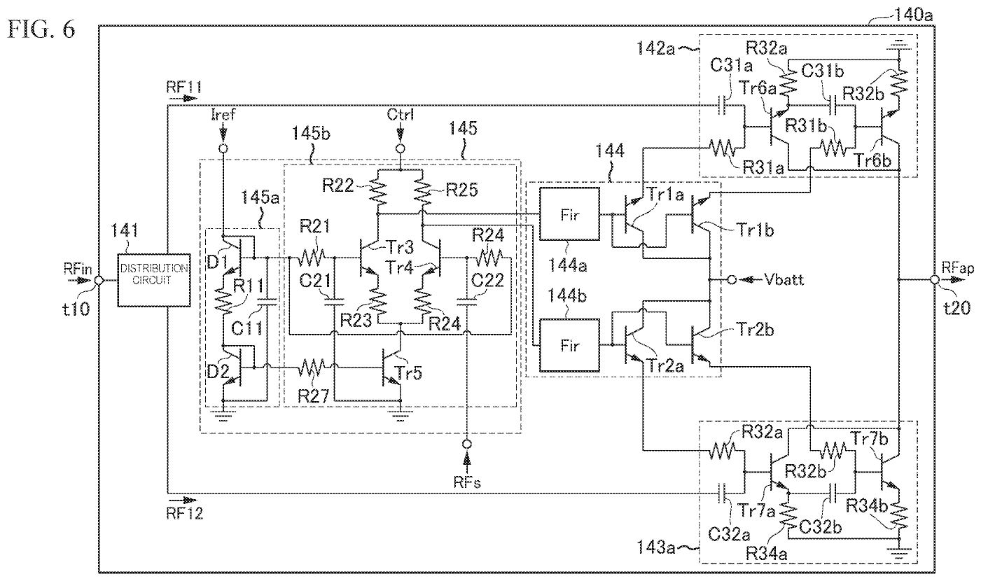

A first modification example of the power amplifier circuit 100a will be described with reference to FIG. 6. FIG. 6 is a diagram showing a configuration example of a distortion compensation amplifier circuit 140a according to the first modification example.

As shown in FIG. 6, in the distortion compensation amplifier circuit 140a according to the first modification example, an amplifier 142a and an amplifier 143a are configured to include transistors that are Darlington-connected through a capacitor.

The amplifier 142a includes a transistor Tr6a, a transistor Tr6b, a resistor R31a, a resistor R31a, a resistor R32a, a resistor R32b, a capacitor C31a, and a capacitor C31b.

The transistor Tr6a (first anterior stage transistor) has a base that receives the signal RF11 through the capacitor C31a, an emitter that is electrically coupled to the reference potential through the resistor R32a, and a collector that is electrically connected to the output terminal t20. The base of the transistor Tr6a is electrically connected to an emitter of a transistor tr1a of the bias circuit 144 through the resistor R31a, and is supplied with the bias.

The transistor Tr6b (first posterior stage transistor) has a base that is electrically connected to the emitter of the transistor Tr6a through the capacitor C31b, an emitter that is electrically coupled to the reference potential through the resistor R32b, and a collector that is electrically connected to the output terminal t20. In other words, the base of the transistor Tr6b is electrically coupled to the reference potential through the capacitor C31b. Further, the base of the transistor Tr6b is electrically connected to an emitter of a transistor tr1b of the bias circuit 144 through the resistor R31b, and is supplied with the bias.

The bias circuit 144 includes the transistor Tr1a and the transistor tr1b through which the amplifier 142a supplies the bias to each of the transistor tr6a and the transistor tr6b that are Darlington-connected. Since each of the transistor Tr1a and the transistor tr1b is the same as the transistor Tr1, the description thereof is omitted.

As described above, the amplifier 142a is configured by the Darlington connection of the transistor Tr6a and the transistor Tr6b through the capacitor C31b. In the normal Darlington connection, the two transistors are electrically connected without necessarily the capacitor C31b. In this case, a base potential of the transistor Tr6a rises by two base-emitter voltages of a base-emitter voltage of the transistor Tr6b and a base-emitter voltage of the transistor Tr6a. Further, the transistor Tr6a is supplied with the bias from the transistor Tr1a of the bias circuit 144. That is, when the transistor Tr6a and the transistor Tr6b are Darlington-connected without necessarily the capacitor C31b, three base-emitter voltages are required for a power supply voltage supplied to a collector of the transistor Tr1a in the bias circuit 144, and thus a problem arises in that a high power supply voltage needs to be used.

In the distortion compensation amplifier circuit 140a according to the first modification example, with the Darlington connection of the transistor Tr6a and the transistor Tr6b through the capacitor C31b, the configuration can be made with a low power supply voltage. Specifically, since the base of the transistor Tr6b is electrically coupled to the reference potential through the capacitor C31b, a line of the capacitor C31b becomes a DC path. Therefore, the base potential of the transistor Tr6a rises only by one base-emitter voltage, whereas the base potential of the transistor Tr6a rises by two base-emitter voltages when the capacitor C31b is not provided.

Accordingly, the power amplifier circuit 100a can compensate for the phase change at a low power supply voltage Vbatt.

### Second Modification Example

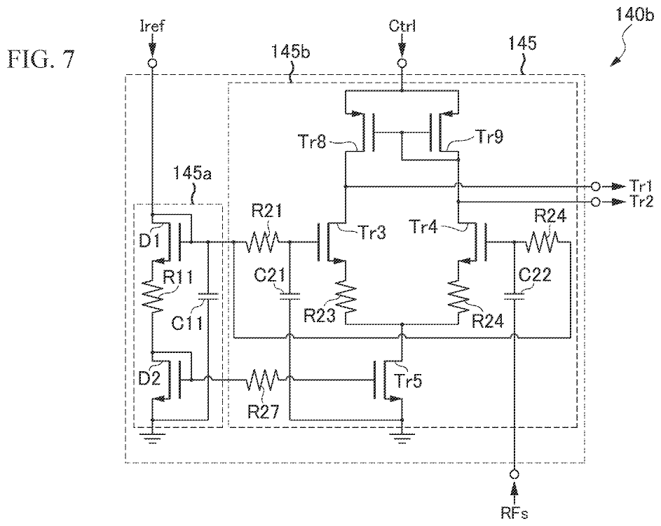

A second modification example of the power amplifier circuit 100a will be described with reference to FIG. 7. FIG. 7 is a diagram showing a configuration example of a distortion compensation amplifier circuit 140b according to the second modification example.

As shown in FIG. 7, the distortion compensation amplifier circuit 140b according to the second modification example is configured of the metal-oxide-semiconductor field-effect transistor, instead of the bipolar transistor in the above. Further, in the bias control circuit 145b of the distortion compensation amplifier circuit 140b according to the second modification example, the control signal ctrl is input to a drain of the transistor Tr3 through a transistor Tr8, which is the metal-oxide-semiconductor field-effect transistor, instead of the resistance element (resistor R22 in FIG. 3), and the control signal ctrl is input to a drain of the transistor Tr4 through a transistor Tr9, which is the metal-oxide-semiconductor field-effect transistor, instead of the resistance element (resistor R25 in FIG. 3). A source and a gate of the transistor Tr9 are electrically connected to each other.

In the distortion compensation amplifier circuit 140b according to the second modification example, with the use of the transistor Tr8 and the transistor tr9, which are active loads, instead of the resistance elements in the bias control circuit 145b, a problem that an output voltage becomes unstable due to a variation in an absolute value of a resistance value can be eliminated.

### Third Modification Example

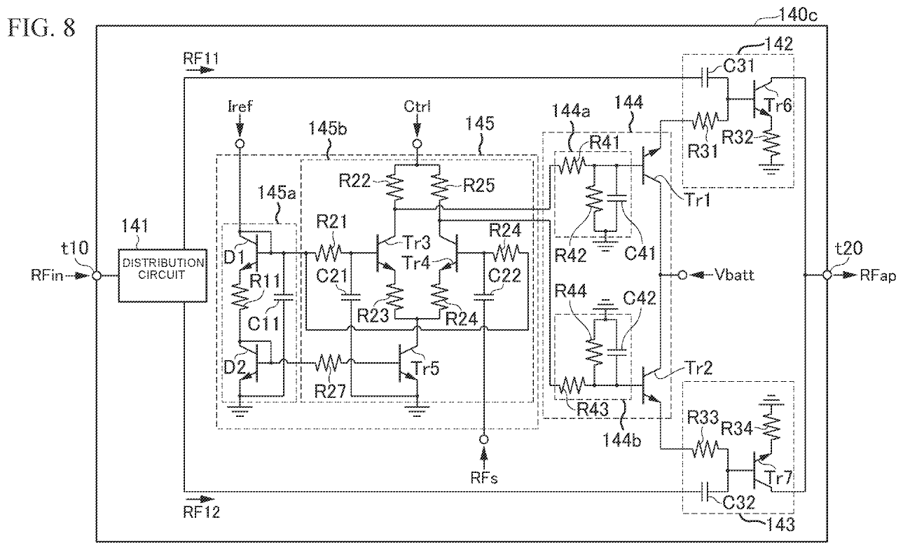

A third modification example of the power amplifier circuit 100a will be described with reference to FIG. 8. FIG. 8 is a diagram showing a configuration example of a distortion compensation amplifier circuit 140c according to the third modification example.

As shown in FIG. 8, the bias circuit 144 of the distortion compensation amplifier circuit 140c according to the third modification example includes a filter circuit 144a and a filter circuit 144b, which are formed of a capacitor and resistors.

The filter circuit 144a includes a capacitor C41, a resistor R41 (first voltage division resistance element), and a resistor R42 (first resistance element). The capacitor C41 has one end that is electrically connected to the base of the transistor Tr1 and the other end that is electrically coupled to the reference potential. The resistor R41 is connected in parallel with the capacitor C41. The base of the transistor Tr1 is electrically connected to the collector of the transistor Tr3 through the resistor R42. That is, the resistor R42 is connected in series to the base of the transistor Tr1.

The filter circuit 144b includes a capacitor C42, a resistor R43 (second voltage division resistance element), and a resistor R44 (second resistance element). The capacitor C42 has one end that is electrically connected to the base of the transistor Tr2 and the other end that is electrically coupled to the reference potential. The resistor R43 is connected in parallel with the capacitor C42. The base of the transistor Tr2 is electrically connected to the collector of the transistor Tr4 through the resistor R44. That is, the resistor R44 is connected in series to the base of the transistor Tr2.

In the distortion compensation amplifier circuit 140c according to the third modification example, the high frequency component can be appropriately attenuated by a simple circuit design.

### Power Amplifier Circuit 100b According to Second Embodiment

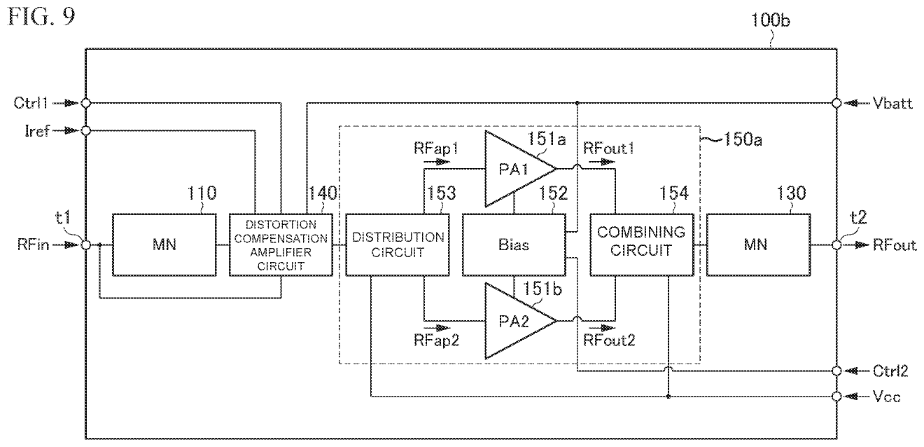

A power amplifier circuit 100b according to a second embodiment will be described with reference to FIG. 9. FIG. 9 is a diagram showing a configuration example of the power amplifier circuit 100b according to the second embodiment. Hereinafter, the description of the matters in common with the power amplifier circuit 100a according to the first embodiment will be omitted, and only different points will be described. Particularly, similar actions and effects achieved by similar configurations will not be repeatedly mentioned.

As shown in FIG. 9, in the power amplifier circuit 100b, the output amplifier circuit 150a is configured of a differential amplifier circuit, as compared with the power amplifier circuit 100a in FIG. 1. Specifically, the output amplifier circuit 150a of the power amplifier circuit 100b includes an amplifier 151a, an amplifier 151b, an output bias circuit 152, a distribution circuit 153, and a combining circuit 154.

The distribution circuit 153 distributes the amplified signal RFap output from the distortion compensation amplifier circuit 140 into a first amplified signal RFap1 and a second amplified signal RFap2 having a phase different from the phase of the first amplified signal RFap1 by 180 degrees. The 180 degrees includes a case of being approximately 180 degrees, and includes, for example, a range of 135 degrees to 225 degrees. The distribution circuit 153 may be, for example, a distributed constant circuit such as a balun or a coupling line 3 dB coupler, a Wilkinson distributor, or a web distributor.

The amplifier 151a amplifies the amplified signal RFap1 and outputs an output signal RFout1. The amplifier 151b amplifies the amplified signal RFap2 and outputs an output signal RFout2. As described above, the output amplifier circuit 150a is configured such that the amplifier 151a and the amplifier 151b form a differential pair.

The output bias circuit 152 supplies the bias to the amplifier 151a and the amplifier 151b.

The combining circuit 154 combines the output signal RFout1 and the output signal RFout2, and outputs the output signal RFout.

In the power amplifier circuit 100b, with the configuration of the output amplifier circuit 150a as the differential pair, the linearity of the gain can be improved in the distortion compensation amplifier circuit 140, and a high-power and high-gain operation is possible.

### Power Amplifier Circuit 100c According to Third Embodiment

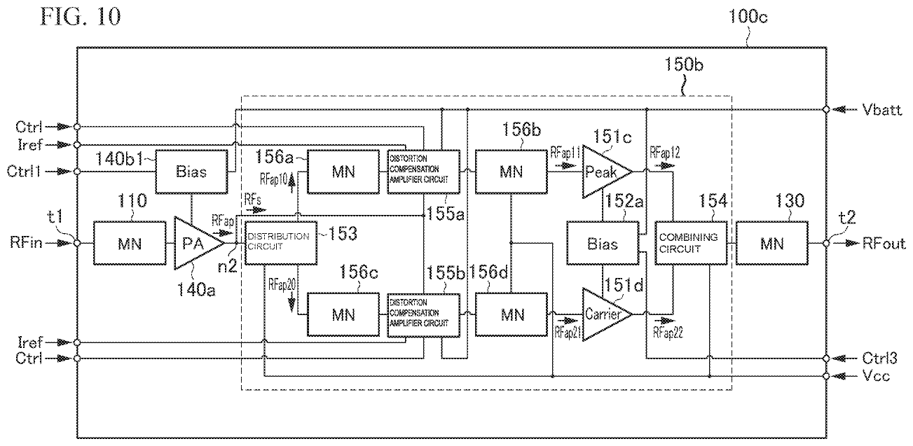

A power amplifier circuit 100c according to a third embodiment will be described with reference to FIG. 10. FIG. 10 is a diagram showing a configuration example of the power amplifier circuit 100c according to the third embodiment. Hereinafter, the description of the matters in common with the power amplifier circuit 100a according to the first embodiment will be omitted, and only different points will be described. Particularly, similar actions and effects achieved by similar configurations will not be repeatedly mentioned.

In the power amplifier circuit 100c, an output amplifier circuit 150b is configured with a Doherty amplifier circuit, as compared with the power amplifier circuit 100a of FIG. 1. In the power amplifier circuit 100c, for example, a configuration is made such that a driver-stage amplifier circuit includes the amplifier circuit 140a that does not have the function of adjusting the phase characteristic, instead of the distortion compensation amplifier circuit 140 in FIG. 1, and the output amplifier circuit 150b includes amplifier circuits (distortion compensation amplifier circuits 155 and 156) having the function of the distortion compensation amplifier circuit 140 of the power amplifier circuit 100a.

The output amplifier circuit 150b includes a peak amplifier circuit 151c, a carrier amplifier circuit 151d, a bias circuit 152a, the distribution circuit 153, the combining circuit 154, the distortion compensation amplifier circuit 155, and inter-stage matching circuits 156a to 156d.

The distribution circuit 153 distributes the amplified signal RFap output from the driver-stage amplifier circuit 140a into an amplified signal RFap10 and an amplified signal RFap20 having a phase different from the phase of the amplified signal RFap10 by 90 degrees. The distribution circuit 153 may be configured to include, for example, a distributed constant circuit such as a balun or a coupling line 3 dB coupler, a Wilkinson distributor, or a web distributor.

The distortion compensation amplifier circuit 155 includes a distortion compensation amplifier circuit 155a and a distortion compensation amplifier circuit 155b. The distortion compensation amplifier circuit 155a and the distortion compensation amplifier circuit 155b have, for example, the same function as the distortion compensation amplifier circuit 140 in FIG. 1. That is, the input control signal RFs branched at a node n2 from an amplified signal (signal corresponding to the input signal RFin) output from the driver-stage amplifier circuit 140 is input to the distortion compensation amplifier circuit 155a and the distortion compensation amplifier circuit 155b. Further, the distortion compensation amplifier circuit 155a and the distortion compensation amplifier circuit 155b include, for example, an amplifier (third amplifier, fifth amplifier) corresponding to the amplifier 142 in the distortion compensation amplifier circuit 140 in FIG. 1 and an amplifier (fourth amplifier, sixth amplifier) corresponding to the amplifier 143 therein, respectively.

The distortion compensation amplifier circuit 155a (first amplifier circuit) controls, based on the input control signal RFs, a gain (third gain) of the amplifier (third amplifier) corresponding to the amplifier 142 in FIG. 3 and a gain (fourth gain) of the amplifier (fourth amplifier) corresponding to the amplifier 143 in FIG. 3 to compensate for a change in the phase of the peak amplifier circuit 151c with respect to a change in the power of a signal input to the peak amplifier circuit 151c, which will be described below. The configuration of the distortion compensation amplifier circuit 155a is assumed to be the same configuration as that in FIG. 3, and the description thereof is omitted. The distortion compensation amplifier circuit 155a amplifies the amplified signal RFap10 and outputs an amplified signal RFap11.

The distortion compensation amplifier circuit 155b (second amplifier circuit) controls, based on the power of the input control signal RFs, a gain (fifth gain) of the amplifier (fifth amplifier) corresponding to the amplifier 142 in FIG. 3 and a gain (sixth gain) of the amplifier (sixth amplifier) corresponding to the amplifier 143 in FIG. 3 to compensate for a change in the phase of the carrier amplifier circuit 151d with respect to a change in the power of a signal input to the carrier amplifier circuit 151d, which will be described below. The configuration of the distortion compensation amplifier circuit 155b is assumed to be the same configuration as that in FIG. 3, and the description thereof is omitted. The distortion compensation amplifier circuit 155b amplifies the amplified signal RFap20 and outputs an amplified signal Rfap21.

The amplified signal Rfap11 output from the distortion compensation amplifier circuit 155a is input to the peak amplifier circuit 151c through the inter-stage matching circuit 156a. The peak amplifier circuit 151c amplifies the amplified signal Rfap11 and outputs an amplified signal Rfap12. The peak amplifier circuit 151c has an amplification action in, for example, a region in which a voltage level of the input signal is equal to or higher than a predetermined power level. Further, the peak amplifier circuit 151c may be biased to class A, class AB, class B, and class C depending on use conditions.

The amplified signal Rfap21 output from the distortion compensation amplifier circuit 155b is input to the carrier amplifier circuit 151d through the inter-stage matching circuit 156b. The carrier amplifier circuit 151d amplifies the amplified signal Rfap21 and outputs an amplified signal Rfap22. The carrier amplifier circuit 151d is biased, for example, to class A, class AB, or class B. That is, the carrier amplifier circuit 151d amplifies the input signal and outputs an amplified signal, regardless of the power level of the input signal, such as small instantaneous input power.

The combining circuit 154 outputs the output signal Rfout obtained by combining, for example, the amplified signal Rfap12 output from the peak amplifier circuit 151c and the amplified signal Rfap22 output from the carrier amplifier circuit 151d.

In the power amplifier circuit 100c, for example, with the configuration of the output amplifier circuit 150b by the Doherty amplifier circuit, a load impedance value becomes, when the peak amplifier circuit 151c operates, half due to the operation. Accordingly, a back-off efficiency of the power amplifier circuit 100c is improved. Further, in the power amplifier circuit 100c, the carrier amplifier circuit 151d and the peak amplifier circuit 151c of the output amplifier circuit 150b are respectively provided with the distortion compensation amplifier circuits 155a and 155b for improving the phase change based on the change in the power of the input signal Rfin, and thus the linearity of the gain can be improved.

### Fourth Modification Example

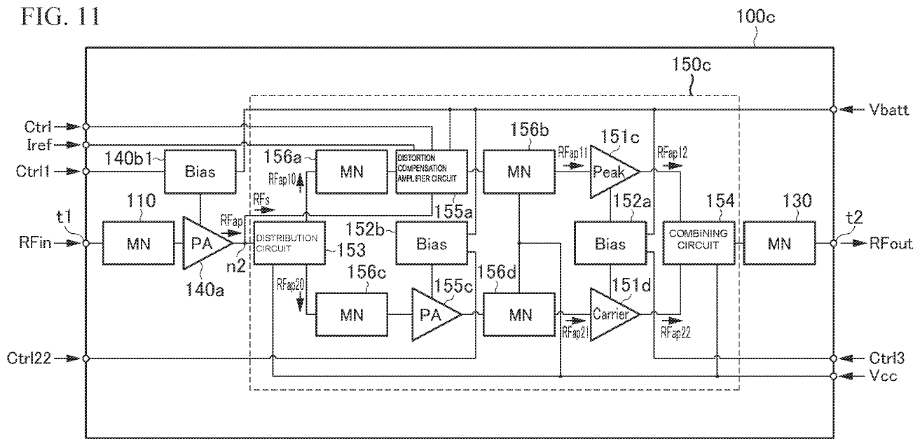

A modification example of the power amplifier circuit 100c according to the third embodiment will be described with reference to FIG. 11. FIG. 11 is a diagram showing the modification example of the power amplifier circuit 100c according to the third embodiment.

As shown in FIG. 11, in the power amplifier circuit 100c according to a fourth modification example, as compared with the power amplifier circuit 100c of FIG. 10, an output amplifier circuit 150c has a configuration in which the peak amplifier circuit 151c is provided with the distortion compensation amplifier circuits 155a while the carrier amplifier circuit 151d is provided with, instead of the distortion compensation amplifier circuit 155b shown in FIG. 10, an amplifier circuit 155c that does not have the function of adjusting the phase characteristic. In other words, the power amplifier circuit 100c according to the fourth modification example is configured to compensate for the phase characteristic of only the peak amplifier circuit 151c.

Since the peak amplifier circuit 151c needs to be operated at a lower bias than that of the carrier amplifier circuit 151d, the phase of the output signal is likely to be distorted from the phase of the output signal of the carrier amplifier circuit 151d. In the power amplifier circuit 100c according to the fourth modification example, with the compensation for the change in the phase of the peak amplifier circuit 151c in which the phase of the output signal is more distorted, the linearity of the gain can be improved with a simple circuit configuration.

### Fifth Modification Example

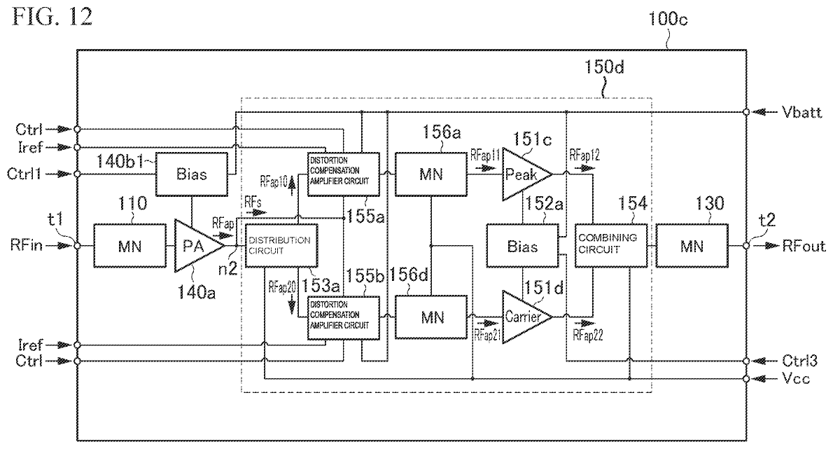

A modification example of the power amplifier circuit 100c according to the third embodiment will be described with reference to FIG. 12. FIG. 12 is a diagram showing the modification example of the power amplifier circuit 100c according to the third embodiment.

As shown in FIG. 12, in the power amplifier circuit 100c according to a fifth modification example, as compared with the power amplifier circuit 100c of FIG. 10, a distribution circuit 153a of an output amplifier circuit 150d distributes the amplified signal Rfap into, for example, the amplified signal Rfap10 and the amplified signal Rfap20 having the same phase as the Rfap10.

The distortion compensation amplifier circuit 155b adjusts the phase of the amplified signal Rfap20 to be different from the phase of the amplified signal Rfap10 by 90 degrees. Further, the distortion compensation amplifier circuit 155b controls, based on the power of the input control signal RFs, the gain (fifth gain) of the amplifier (fifth amplifier) corresponding to the amplifier 142 in FIG. 3 and the gain (sixth gain) of the amplifier (sixth amplifier) corresponding to the amplifier 143 in FIG. 3 to compensate for the change in the phase of the carrier amplifier circuit 151d with respect to the change in the power of the signal input to the carrier amplifier circuit 151d. The configuration of the distortion compensation amplifier circuit 155b is assumed to be the same configuration as that in FIG. 3, and the description thereof is omitted. In FIG. 12, each of the distortion compensation amplifier circuits 155a and 155b is described as being provided at the previous stage of each of the peak amplifier circuit 151c and the carrier amplifier circuit 151d, but the present disclosure is not limited thereto. For example, the distortion compensation amplifier circuit may be provided only at the previous stage of the peak amplifier circuit 151c or only at the previous stage of the carrier amplifier circuit 151d.

In the power amplifier circuit 100c according to the fifth modification example, the number of inter-stage matching circuits can be reduced and the change in the phase of the peak amplifier circuit 151c and the carrier amplifier circuit 151d can be compensated for. Therefore, the linearity can be improved by a simple circuit configuration.

### Disposition of Power Amplifier Circuit

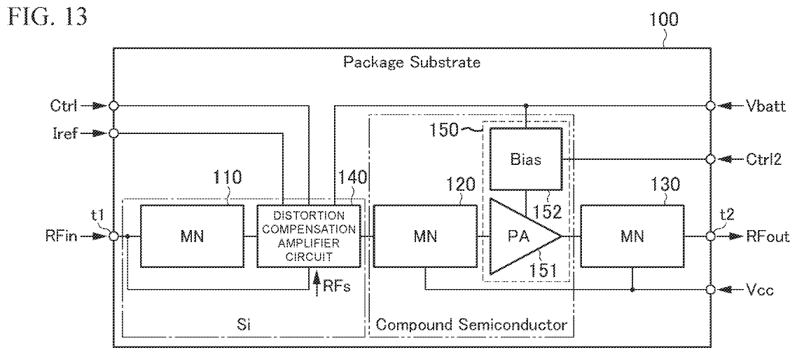

The disposition of each component of the power amplifier circuit 100a will be described with reference to FIG. 13. FIG. 13 is a diagram showing a disposition example of each component of the power amplifier circuit 100a.

As shown in FIG. 13, in the power amplifier circuit 100a, for example, the input matching circuit 110 and the distortion compensation amplifier circuit 140 are implemented on a semiconductor integrated circuit (one-dot chain line in FIG. 13) whose substrate material contains silicon, the inter-stage matching circuit 120 and the output amplifier circuit 150 are implemented on an integrated circuit (two-dot chain line in FIG. 13) having a compound semiconductor substrate, and the output matching circuit 130 is implemented on a package substrate. The compound semiconductor substrate is configured with, for example, gallium arsenide.

That is, the power amplifier circuit 100a is configured with two chips of a silicon chip in which the driver-stage amplifier circuit is formed and a compound chip in which a power-stage amplifier circuit is formed. As described above, in the power amplifier circuit 100a, with the formation of the driver-stage amplifier circuit on the silicon chip, the wiring can be miniaturized, the size of the circuit can be reduced, and the cost can be reduced.

The disposition of each component of the power amplifier circuit shown in FIGS. 9 to 12 will be described below.

In the power amplifier circuit 100b shown in FIG. 9, the input matching circuit 110 and the distortion compensation amplifier circuit 140 may be implemented on a semiconductor integrated circuit having silicon as a substrate material, the distribution circuit 153 and an output amplifier circuit 150a may be implemented on an integrated circuit having a compound semiconductor substrate, and the output matching circuit 130 may be implemented on a package substrate.

In the power amplifier circuit 100c shown in FIG. 10, the input matching circuit 110, the amplifier circuit 140a, a bias circuit 140b1, the distribution circuit 153, the inter-stage matching circuits 156a and 156c, and the distortion compensation amplifier circuits 155a and 155b may be implemented on a semiconductor integrated circuit having silicon as a substrate material, the inter-stage matching circuits 156b and 156d, the peak amplifier circuit 151c, the carrier amplifier circuit 151d, the bias circuit 152a, and the combining circuit 154 may be implemented on an integrated circuit having a compound semiconductor substrate, and the output matching circuit 130 may be implemented on a package substrate. Similarly, in FIGS. 11 and 12, each component on an input side of the inter-stage matching circuits 156b and 156d is implemented on a semiconductor integrated circuit having silicon as a substrate material.

Accordingly, similarly to the power amplifier circuit 100a, in the power amplifier circuit 100b and the power amplifier circuit 100c, the wiring can be miniaturized, the size of the circuit can be reduced, and the cost can be reduced.

### SUMMARY

<1> A power amplifier circuit 100a according to an exemplary embodiment of the present disclosure includes:
a distortion compensation amplifier circuit 140 that includes
   an amplifier 142 (first amplifier) that amplifies a signal RF11 (first signal) distributed from an input signal RFin with a first gain, and
   an amplifier 143 (second amplifier), which is connected in parallel to the amplifier 142 (first amplifier), that amplifies a signal RF12 (second signal) distributed from the input signal Rfin and having a different phase from the signal RF11 (first signal) with a second gain, and
outputs an amplified signal Rfap obtained by combining a signal output from the amplifier 142 (first amplifier) and a signal output from the amplifier 143 (second amplifier); and
an output amplifier circuit 150 that outputs an output signal Rfout obtained by amplifying the amplified signal Rfap,
in which the distortion compensation amplifier circuit 140 further includes a control circuit 145 that controls, based on power of the input signal Rfin, the first gain and the second gain to compensate for a change in a phase of the output amplifier circuit 150 with respect to a change in the power of the signal input to the output amplifier circuit 150. Accordingly, the power amplifier circuit 100a can improve, under a wider operating condition, the linearity of the gain and improve the signal quality.

<2> In the power amplifier circuit 100a according to the exemplary embodiment of the present disclosure, the distortion compensation amplifier circuit 140 further includes a bias circuit 144 that supplies a first bias to the amplifier 142 (first amplifier) and a second bias to the amplifier 143 (second amplifier), and the control circuit 145 controls the first bias and the second bias based on the power of the input signal Rfin. Accordingly, the power amplifier circuit 100a can improve the linearity of the gain and improve the signal quality.

<3> In the power amplifier circuit 100a according to the exemplary embodiment of the present disclosure, the power amplifier circuit according to <1> or <2>, the bias circuit 144 includes a transistor Tr1 (first transistor) that supplies the first bias to the amplifier 142 (first amplifier), and a transistor Tr2 (second transistor) that supplies the second bias to the amplifier 143 (second amplifier), the control circuit 145 includes a differential circuit that configures a differential pair with a transistor Tr3 (third transistor) and a transistor Tr4 (fourth transistor), and a transistor Tr5 (fifth transistor) that extracts a current from a connection point between an emitter or a source of the transistor Tr3 (third transistor) and an emitter or a source of the transistor Tr4 (fourth transistor), the transistor Tr3 (third transistor) has a collector or a drain that is electrically connected to a base or a gate of the transistor Tr1 (first transistor), and the emitter or the source that is electrically connected to a collector or a drain of the transistor Tr5 (fifth transistor), and the transistor Tr4 (fourth transistor) has a base or a gate that is supplied with the power of the input signal RFin, a collector or a drain that is electrically connected to a base or a gate of the transistor Tr2 (second transistor), and the emitter or the source that is electrically connected to the collector or the drain of the transistor Tr5 (fifth transistor). Accordingly, the power amplifier circuit 100a can improve the linearity of the gain and improve the signal quality.

<4> In the power amplifier circuit 100b according to the exemplary embodiment of the present disclosure, the power amplifier circuit according to any one of <1> to <3>, the output amplifier circuit 150a includes a distribution circuit 153 (second distribution circuit) that distributes the amplified signal RFap into an amplified signal RFap1 (first amplified signal) and an amplified signal RFap2 (second amplified signal) having a phase different from a phase of the amplified signal RFap1 (first amplified signal) by 180 degrees, an amplifier 151a (third amplifier) that outputs an output signal RFout1 (first output signal) obtained by amplifying the amplified signal RFap1 (first amplified signal), an amplifier 151b (fourth amplifier) that outputs an output signal RFout2 (second output signal) obtained by amplifying the amplified signal RFap2 (second amplified signal), and a combining circuit 154 that outputs the output signal RFout obtained by combining the output signal RFout1 (first output signal) and the output signal RFout2 (second output signal). Accordingly, in the power amplifier circuit 100b, the linearity of the gain can be improved in the distortion compensation amplifier circuit 140, and a high-power and high-gain operation is possible.

<5> In the power amplifier circuit 100c according to the exemplary embodiment of the present disclosure, the power amplifier circuit according to any one of <1> to <3>, the distortion compensation amplifier circuit includes a distortion compensation amplifier circuit 155a (first amplifier circuit) that outputs an amplified signal RFap11 (first amplified signal) obtained by amplifying an amplified signal RFap10 (first input signal) distributed from the input signal RFin (amplified signal RFap in FIG. 10), and an amplifier circuit 155c (second amplifier circuit) that outputs an amplified signal RFap21 (second amplified signal) obtained by amplifying an amplified signal RFap20 (second input signal) distributed from the input signal RFin (amplified signal RFap in FIG. 10) and having a different phase from the amplified signal RFap10 (first input signal) by 90 degrees, the output amplifier circuit 150b includes a peak amplifier circuit 151c that amplifies the amplified signal RFap11 (first amplified signal), and a carrier amplifier circuit 151d that amplifies the amplified signal RFap21 (second amplified signal), and the distortion compensation amplifier circuit 155a (first amplifier circuit) includes a third amplifier (amplifier 142 in FIG. 3) that amplifies a third signal (signal RF11 in FIG. 3) distributed from the amplified signal RFap10 (first input signal) with a third gain, a fourth amplifier (amplifier 143 in FIG. 3), which is connected in parallel to the third amplifier (amplifier 142 in FIG. 3), that amplifies a fourth signal (signal RF12 in FIG. 3) distributed from the amplified signal RFap10 (first input signal) and having a different phase from the third signal (signal RF11 in FIG. 3) with a fourth gain, and a first control circuit (control circuit 145 in FIG. 3) that controls, based on the power of the input signal RFin, the third gain and the fourth gain to compensate for a change in a phase of the peak amplifier circuit 151c with respect to a change in the power of the signal input to the peak amplifier circuit 151c. Accordingly, the power amplifier circuit 100c can improve the back-off efficiency and the gain linearity.

<6> In the power amplifier circuit 100c according to the exemplary embodiment of the present disclosure, the power amplifier circuit according to <5>, the distortion compensation amplifier circuit 155b (second amplifier circuit) includes a fifth amplifier (amplifier 142 in FIG. 3) that amplifies a fifth signal (signal RF11 in FIG. 3) distributed from the amplified signal RFap20 (second input signal) with a fifth gain, a sixth amplifier (amplifier 143 in FIG. 3), which is connected in parallel to the fifth amplifier (amplifier 142 in FIG. 3), that amplifies a sixth signal (signal RF12 in FIG. 3) distributed from the amplified signal RFap20 (second input signal) and having a different phase from the fifth signal (signal RF11 in FIG. 3) with a sixth gain, and a second control circuit (control circuit 145 in FIG. 3) that controls, based on the power of the input signal RFin, the fifth gain and the sixth gain to compensate for a change in a phase of the carrier amplifier circuit 151d with respect to a change in the power of the signal input to the carrier amplifier circuit 151d. Accordingly, the power amplifier circuit 100c can improve the back-off efficiency and the gain linearity.

<7> In the power amplifier circuit 100c according to the exemplary embodiment of the present disclosure, the power amplifier circuit according to any one of <1> to <3>, the distortion compensation amplifier circuit includes a distortion compensation amplifier circuit 155a (first amplifier circuit) that outputs an amplified signal RFap11 (first amplified signal) obtained by amplifying an amplified signal RFap10 (first input signal) distributed from the input signal RFin, and a distortion compensation amplifier circuit 155b (second amplifier circuit) that outputs an amplified signal RFap21 (second amplified signal) obtained by amplifying an amplified signal RFap20 (second input signal) distributed from the input signal RFin, the output amplifier circuit 150d includes a peak amplifier circuit 151c that amplifies the amplified signal RFap11 (first amplified signal), and a carrier amplifier circuit 151d that amplifies the amplified signal RFap21 (second amplified signal), the distortion compensation amplifier circuit 155a (first amplifier circuit) includes a third amplifier (amplifier 142 in FIG. 3) that amplifies a third signal distributed from the amplified signal RFap10 (first input signal) with a third gain, a fourth amplifier (amplifier 143 in FIG. 3), which is connected in parallel to the third amplifier (amplifier 142 in FIG. 3), that amplifies a fourth signal distributed from the amplified signal RFap10 (first input signal) and having a different phase from the third signal with a fourth gain, and a first control circuit (control circuit 145 in FIG. 3) that controls, based on the power of the input signal RFin, the third gain and the fourth gain to compensate for a change in a phase of the peak amplifier circuit 151c with respect to a change in the power of the signal input to the peak amplifier circuit 151c, the distortion compensation amplifier circuit 155b (second amplifier circuit) includes a fifth amplifier (amplifier 142 in FIG. 3) that amplifies a fifth signal distributed from the amplified signal RFap20 (second input signal) with a fifth gain, a sixth amplifier (amplifier 143 in FIG. 3), which is connected in parallel to the fifth amplifier (amplifier 142 in FIG. 3), that amplifies a sixth signal distributed from the amplified signal RFap20 (second input signal) and having a different phase from the fifth signal with a sixth gain, and a second control circuit (control circuit 145 in FIG. 3) that controls, based on the power of the input signal RFin, the fifth gain and the sixth gain to compensate for a change in a phase of the carrier amplifier circuit 151d with respect to a change in the power of the signal input to the carrier amplifier circuit 151d, and at least one of the first control circuit (control circuit 145 in FIG. 3) and the second control circuit (control circuit 145 in FIG. 3) adjusts a phase of the amplified signal RFap20 (second input signal) to be different from a phase of the amplified signal RFap10 (first input signal) by 90 degrees. Accordingly, in the power amplifier circuit 100c, the number of inter-stage matching circuits can be reduced and the phase change of the peak amplifier circuit 151c and the carrier amplifier circuit 151d can be compensated for. Therefore, the linearity can be improved with a simple circuit configuration.

<8> In the power amplifier circuit 100a according to the exemplary embodiment of the present disclosure, the power amplifier circuit according to any one of <1> to <7>, the amplifier 142a (first amplifier) includes a transistor Tr6a (first anterior stage transistor) that has a base or a gate that receives the signal RF11 (first signal), and an emitter or a source that is electrically coupled to a reference potential, and a transistor Tr6b (first posterior stage transistor) that has an emitter or a source that is electrically coupled to the reference potential, and has a base or a gate that is electrically connected to the emitter or the source of the transistor Tr6a (first anterior stage transistor) through a capacitor C31b (first capacitor), the amplifier 143a (second amplifier) includes a transistor Tr7a (second anterior stage transistor) that has a base or a gate that receives the signal RF12 (second signal), and an emitter or a source that is electrically coupled to the reference potential, and a transistor Tr7b (second posterior stage transistor) that has an emitter or a source that is electrically coupled to the reference potential, and has a base or a gate that is electrically connected to the emitter or the source of the transistor Tr7a (second anterior stage transistor) through a capacitor 32b (second capacitor), and the distortion compensation amplifier circuit 140a outputs the amplified signal RFap from a connection point between a collector or a drain of the transistor Tr6b (first posterior stage transistor) and a collector or a drain of the transistor Tr7b (second posterior stage transistor). Accordingly, the power amplifier circuit 100a can compensate for the phase change at a low power supply voltage Vbatt.

<9> In the power amplifier circuit 100a according to the exemplary embodiment of the present disclosure, the power amplifier circuit according to any one of <1> to <8>, the bias circuit 144 includes a transistor Tr1 (first transistor) that supplies the first bias to the amplifier 142 (first amplifier), a transistor Tr2 (second transistor) that supplies the second bias to the amplifier 143 (second amplifier), a filter circuit 144a (first filter circuit) that attenuates a high frequency component, and a filter circuit 144b (second filter circuit) that attenuates the high frequency component, the transistor Tr1 (first transistor) has a base or a gate that receives a signal for controlling the first bias from the control circuit 145 through the filter circuit 144a (first filter circuit), and the transistor Tr2 (second transistor) has a base or a gate that receives a signal for controlling the second bias from the control circuit 145 through the filter circuit 144b (second filter circuit). Accordingly, the power amplifier circuit 100a can appropriately attenuate the high frequency component with a simple circuit design.

<10> In the power amplifier circuit 100a according to the exemplary embodiment of the present disclosure, the power amplifier circuit according to <9>, the filter circuit 144a (first filter circuit) includes a resistor R41 (first resistance element) that is connected in series to the base or the gate of the transistor Tr1 (first transistor), a capacitor C41 (first capacitor) having one end that is electrically connected to the base or the gate of the transistor Tr1 (first transistor) and the other end that is coupled to a reference potential, and a resistor R42 (first voltage division resistance element) that is connected in parallel to the capacitor C41 (first capacitor), and the filter circuit 144b (second filter circuit) includes a resistor R43 (second resistance element) that is connected in series to the base or the gate of the transistor Tr2 (second transistor), a capacitor C42 (second capacitor) having one end that is electrically connected to the base or the gate of the transistor Tr2 (second transistor) and the other end that is coupled to the reference potential, and a resistor R44 (second voltage division resistance element) that is connected in parallel to the capacitor C42 (second capacitor). Accordingly, the power amplifier circuit 100a can appropriately attenuate the high frequency component with a simple circuit design.

<11> In the power amplifier circuit 100a according to the exemplary embodiment of the present disclosure, the power amplifier circuit according to any one of <1> to <10>, the transistor Tr1 (first transistor), the transistor Tr2 (second transistor), the transistor Tr3 (third transistor), the transistor Tr4 (fourth transistor), and the transistor Tr5 (fifth transistor) are configured of metal-oxide-semiconductor field-effect transistors. Accordingly, the power amplifier circuit 100a can operate at a low power supply voltage.

<12> In the power amplifier circuit 100a according to the exemplary embodiment of the present disclosure, the power amplifier circuit according to <11>, in the control circuit 145, a control signal ctrl for adjusting a magnitude of the first bias is input to the drain of the transistor Tr3 (third transistor) through a transistor Tr8 (first metal-oxide-semiconductor field-effect transistor), and the control signal ctrl is input to the drain of the transistor Tr4 (fourth transistor) through a transistor Tr9 (second metal-oxide-semiconductor field-effect transistor). Accordingly, the power amplifier circuit 100a can eliminate the problem that the output voltage becomes unstable due to the variation in the absolute value of the resistance value.

<13> In the power amplifier circuit 100a according to the exemplary embodiment of the present disclosure, the power amplifier circuit according to any one of <1> to <12>, the distortion compensation amplifier circuit 140 is formed on a silicon substrate, and the output amplifier circuit 150 is formed on a compound semiconductor substrate. Accordingly, in the power amplifier circuit 100a, with the formation of the driver-stage amplifier circuit on the silicon chip, the wiring can be miniaturized, the size of the circuit can be reduced, and the cost can be reduced.

Each embodiment described above is for easy understanding of the present disclosure, and is not for limitedly interpreting the present disclosure. The present disclosure may be changed or improved without necessarily departing from the gist thereof, and the present disclosure also includes equivalents thereof. That is, those in which design changes are made as appropriate to each embodiment by a person skilled in the art are included in the scope of the present disclosure as long as they have the features of the present disclosure. For example, each element provided in each embodiment and the disposition, material, condition, shape, size, and the like thereof are not limited to those illustrated and can be changed as appropriate. Further, each element of each embodiment can be combined to the extent technically possible, and combinations thereof are also included in the scope of the present disclosure as long as they include the features of the present disclosure.

What is claimed is:

1. A power amplifier circuit comprising:
a distortion compensation amplifier circuit that comprises:
a first amplifier configured to amplify a first signal distributed from an input signal with a first gain,
a second amplifier configured to amplify a second signal that is distributed from the input signal with a second gain, a phase of the second signal being different from a phase of the first signal, and the second amplifier being connected in parallel to the first amplifier, and
a control circuit,
wherein the distortion compensation is configured to output an amplified signal obtained by combining a signal output from the first amplifier and a signal output from the second amplifier; and
an output amplifier circuit configured to output an output signal obtained by amplifying the amplified signal,
wherein the control circuit is configured to control the first gain and the second gain based on power of the input signal, thereby compensating for a change in a phase of the output amplifier circuit with respect to a change in the power of the signal input to the output amplifier circuit.

2. The power amplifier circuit according to claim 1,
wherein the distortion compensation amplifier circuit further comprises a bias circuit configured to supply a first bias to the first amplifier and a second bias to the second amplifier, and
wherein the control circuit is further configured to control the first bias and the second bias based on the power of the input signal.

3. The power amplifier circuit according to claim 2,
wherein the bias circuit comprises:
a first transistor configured to supply the first bias to the first amplifier, and
a second transistor configured to supply the second bias to the second amplifier,
wherein the control circuit comprises:
a differential circuit comprising a third transistor and a fourth transistor arranged as a differential pair, and
a fifth transistor configured to extract a current from a node between an emitter or a source of the third transistor and an emitter or a source of the fourth transistor,
wherein the third transistor has a collector or a drain that is electrically connected to a base or a gate of the first transistor, and the emitter or the source of the third transistor is electrically connected to a collector or a drain of the fifth transistor, and
wherein the fourth transistor has a base or a gate that is supplied with the power of the input signal, a collector or a drain that is electrically connected to a base or a gate of the second transistor, and the emitter or the source of the fourth transistor is electrically connected to the collector or the drain of the fifth transistor.

4. The power amplifier circuit according to claim 1, wherein the output amplifier circuit comprises:
a second distribution circuit configured to distribute the amplified signal into a first amplified signal and a second amplified signal, a phase of the second amplified signal being different from a phase of the first amplified signal by 180 degrees,
a third amplifier configured to output a first output signal obtained by amplifying the first amplified signal,
a fourth amplifier configured to output a second output signal obtained by amplifying the second amplified signal, and
a combining circuit configured to output the output signal obtained by combining the first output signal and the second output signal.

5. The power amplifier circuit according to claim 1,
wherein the distortion compensation amplifier circuit comprises:
a first amplifier circuit configured to output a first amplified signal obtained by amplifying a first input signal distributed from the input signal, and
a second amplifier circuit configured to output a second amplified signal obtained by amplifying a second input signal distributed from the input signal, a phase of the second input signal being different from a phase of the first input signal by 90 degrees,
wherein the output amplifier circuit comprises:
a peak amplifier circuit configured to amplify the first amplified signal, and
a carrier amplifier circuit configured to amplify the second amplified signal, and
wherein the first amplifier circuit comprises:
a third amplifier configured to amplify a third signal distributed from the first input signal with a third gain,
a fourth amplifier configured to amplify a fourth signal distributed from the first input signal with a fourth gain, the fourth amplifier being connected in parallel to the third amplifier, and a phase of the fourth signal being different from a phase of the third signal, and
a first control circuit configured to control the third gain and the fourth gain based on the power of the input signal, thereby compensating for a change in a phase of the peak amplifier circuit with respect to a change in the power of the signal input to the peak amplifier circuit.

6. The power amplifier circuit according to claim 5, wherein the second amplifier circuit comprises:
a fifth amplifier configured to amplify a fifth signal distributed from the second input signal with a fifth gain,
a sixth amplifier configured to amplify a sixth signal distributed from the second input signal with a sixth gain, the sixth amplifier being connected in parallel to the fifth amplifier, and a phase of the sixth signal being different from a phase of the fifth signal, and
a second control circuit configured to control the fifth gain and the sixth gain based on the power of the input signal, thereby compensating for a change in a phase of the carrier amplifier circuit with respect to a change in the power of the signal input to the carrier amplifier circuit.

7. The power amplifier circuit according to claim 1,
wherein the distortion compensation amplifier circuit comprises:
a first amplifier circuit configured to output a first amplified signal obtained by amplifying a first input signal distributed from the input signal, and
a second amplifier circuit configured to output a second amplified signal obtained by amplifying a second input signal distributed from the input signal,
wherein the output amplifier circuit comprises:
a peak amplifier circuit configured to amplify the first amplified signal, and
a carrier amplifier circuit configured to amplify the second amplified signal,
wherein the first amplifier circuit comprises:
a third amplifier configured to amplify a third signal distributed from the first input signal with a third gain,
a fourth amplifier configured to amplify a fourth signal distributed from the first input signal with a fourth gain, the fourth amplifier being connected in parallel to the third amplifier, and a phase of the fourth signal being different from a phase of the third signal, and
a first control circuit configured to control the third gain and the fourth gain based on the power of the input signal, thereby compensating for a change in a phase of the peak amplifier circuit with respect to a change in the power of the signal input to the peak amplifier circuit,
wherein the second amplifier circuit comprises:
a fifth amplifier configured to amplify a fifth signal distributed from the second input signal with a fifth gain,
a sixth amplifier configured to amplify a sixth signal distributed from the second input signal with a sixth gain, the sixth amplifier being connected in parallel to the fifth amplifier, and a phase of the sixth signal being different from a phase of the fifth signal, and
a second control circuit configured to control the fifth gain and the sixth gain based on the power of the input signal, thereby compensating for a change in a phase of the carrier amplifier circuit with respect to a change in the power of the signal input to the carrier amplifier circuit, and
wherein the first control circuit or the second control circuit is configured to adjust a phase of the second input signal to be different from a phase of the first input signal by 90 degrees.

8. The power amplifier circuit according to claim 1,
wherein the first amplifier comprises:
a first anterior stage transistor that has a base or a gate that receives the first signal, and an emitter or a source that is electrically coupled to a reference potential, and
a first posterior stage transistor that has an emitter or a source that is electrically coupled to the reference potential, and a base or a gate that is electrically connected to the emitter or the source of the first anterior stage transistor through a first capacitor,
wherein the second amplifier comprises:
a second anterior stage transistor that has a base or a gate that receives the second signal, and an emitter or a source that is electrically coupled to the reference potential, and
a second posterior stage transistor that has an emitter or a source that is electrically coupled to the reference potential, and a base or a gate that is electrically connected to the emitter or the source of the second anterior stage transistor through a second capacitor, and
wherein the distortion compensation amplifier circuit is configured to output the amplified signal from a node between a collector or a drain of the first posterior stage transistor and a collector or a drain of the second posterior stage transistor.

9. The power amplifier circuit according to claim 2,
wherein the bias circuit comprises:
a first transistor configured to supply the first bias to the first amplifier,
a second transistor configured to supply the second bias to the second amplifier,
a first filter circuit configured to attenuate a high frequency component, and
a second filter circuit configured to attenuate the high frequency component,
wherein the first transistor has a base or a gate that receives a signal for controlling the first bias from the control circuit through the first filter circuit, and
wherein the second transistor has a base or a gate that receives a signal for controlling the second bias from the control circuit through the second filter circuit.

10. The power amplifier circuit according to claim 9,
wherein the first filter circuit comprises:
a first resistance element that is connected in series to the base or the gate of the first transistor,
a first capacitor having a first end that is electrically connected to the base or the gate of the first transistor and a second end that is coupled to a reference potential, and
a first voltage division resistance element that is connected in parallel to the first capacitor, and
wherein the second filter circuit comprises:
a second resistance element that is connected in series to the base or the gate of the second transistor,
a second capacitor having a first end that is electrically connected to the base or the gate of the second transistor and a second end that is coupled to the reference potential, and
a second voltage division resistance element that is connected in parallel to the second capacitor.

11. The power amplifier circuit according to claim 3, wherein the first transistor, the second transistor, the third transistor, the fourth transistor, and the fifth transistor are metal-oxide-semiconductor field-effect transistors.

12. The power amplifier circuit according to claim 11, wherein in the control circuit:
a control signal for adjusting a magnitude of the first bias is input to the drain of the third transistor through a first metal-oxide-semiconductor field-effect transistor, and
the control signal is input to the drain of the fourth transistor through a second metal-oxide-semiconductor field-effect transistor.

13. The power amplifier circuit according to claim 1,
wherein the distortion compensation amplifier circuit is on a silicon substrate, and
wherein the output amplifier circuit is on a compound semiconductor substrate.
